(19) United States
(12) Patent Application Publication
(10) Pub. No.: US 2025/0205788 A1
(43) Pub. Date: Jun. 26, 2025

(54) CEMENTED CARBIDE AND COATED TOOL AND CUTTING TOOL EACH USING THE SAME

(71) Applicant: KYOCERA CORPORATION, Kyoto-shi, Kyoto (JP)

(72) Inventors: Akihiro KATSUMARU, Satsumasendai-shi, Kagoshima (JP); Naohisa MATSUDA, Satsumasendai-shi, Kagoshima (JP); Tomoya AMAMI, Satsumasendai-shi, Kagoshima (JP)

(21) Appl. No.: 18/851,065

(22) PCT Filed: Mar. 1, 2023
(86) PCT No.: PCT/JP2023/007459

§ 371 Date: Sep. 26, 2024

(30) Foreign Application Priority Data
Mar. 28, 2022 (JP) 2022-051034

(51) Int. Cl. B23B 27/14

(52) U.S. Cl. CPC B23B 27/148; B23B 2228/105

(57) ABSTRACT

A cemented carbide includes a hard phase including W and C, a solid solution phase including W, C, and Ti, and a binding phase including an iron group metal. The cemented carbide includes a β-free layer composed only of WC and an iron group metal on a surface of an intersecting region of a rake surface and a flank surface in the cemented carbide. In the intersecting region, an average thickness of the β-free layer of the rake surface is “a,” an average thickness of the β-free layer of the flank surface is “b,” and b<a. A coated tool includes the cemented carbide and a coating layer on a surface of the cemented carbide. A cutting tool includes a holder that extends from a first end toward a second end and includes a pocket on a side of the first end, and the coated tool in the pocket.

### CROSS-REFERENCE TO RELATED APPLICATION

The present application claims priority to Japanese Patent Application No. 2022-051034, filed Mar. 28, 2022. The contents of this application are incorporated herein by reference in their entirety.

### TECHNICAL FIELD

The present disclosure relates to a cemented carbide, and a coated tool and a cutting tool each using the cemented carbide.

### BACKGROUND

Cemented carbide including WC (tungsten carbide) as a hard phase is used for a base, etc. in a coated tool, and is applied to a cutting tool, such as an end mill. Fracture resistance, etc. are required for the cemented carbide.

As cemented carbide excellent in fracture resistance, for example, Japanese Patent No. 3235259 (Patent Document 1) describes that a β-free layer is present on a cutting edge ridgeline part of the cemented carbide, and also describes a thickness of the β-free layer. Japanese Patent No. 3656838 (Patent Document 2) does not describe that a β-free layer is present on a cutting edge ridgeline part of cemented carbide, but describes adjustment of a thickness of the β-free layer in each of a rake surface and a flank surface.

### SUMMARY

A cemented carbide in a non-limiting embodiment of the present disclosure includes a hard phase including W and C, a solid solution phase including W, C, and Ti, and a binding phase including an iron group metal. The cemented carbide includes a β-free layer composed only of WC and an iron group metal on a surface of an intersecting region of a rake surface and a flank surface in the cemented carbide. An average thickness of the β-free layer of the rake surface in the intersecting region is “a,” and an average thickness of the β-free layer of the flank surface in the intersecting region is “b.” A relationship between the “a” and the “b” satisfies b<a.

A coated tool in a non-limiting embodiment of the present disclosure includes the cemented carbide and a coating layer located on a surface of the cemented carbide.

A cutting tool in a non-limiting embodiment of the present disclosure includes a holder that extends from a first end toward a second end and includes a pocket on a side of the first end, and the coated tool located in the pocket.

### BRIEF DESCRIPTION OF THE DRAWINGS

FIG. 1 is a perspective view illustrating a cemented carbide in a non-limiting embodiment of the present disclosure;

FIG. 2 is a sectional view taken along line II-II in the cemented carbide illustrated in FIG. 1, specifically, a sectional view orthogonal to an intersecting region in top view (plan view) from a rake surface;

FIG. 3 is a sectional view illustrating a neighborhood of a surface of a coated tool in a non-limiting embodiment of the present disclosure;

FIG. 4 is a sectional view illustrating a neighborhood of a surface of a coated tool in a non-limiting embodiment of the present disclosure; and

FIG. 5 is a perspective view illustrating a cutting tool in a non-limiting embodiment of the present disclosure.

### EMBODIMENT

### <Cemented Carbide>

A cemented carbide 1 in a non-limiting embodiment of the present disclosure is described in detail below with reference to the drawings. For the convenience of description, the drawings referred to below illustrate, in simplified form, only main members necessary for describing embodiments. Hence, the cemented carbide 1 may include any arbitrary structural member not illustrated in the drawings referred to. Dimensions of the members in the drawings faithfully represent neither dimensions of actual structural members nor dimensional ratios of these members. These points are also true for a coated tool and a cutting tool described later.

The cemented carbide 1 may include a hard phase, a solid solution phase, and a binding phase.

The hard phase may include W (tungsten) and C (carbon). In other words, the hard phase may include WC. The hard phase may include WC as a main component. The term “main component” as used herein may mean a component having the largest value of percent by mass compared to other components. Specifically, components having top two values of percent by mass among components included in the hard phase may be W and C.

The solid solution phase may include W, C, and Ti (titanium). The solid solution phase may include W, C, and Ti as a main component. That is, a total value of percent by mass of W, C, and Ti may be largest in the solid solution phase. Components having top three values of percent by mass among components included in the solid solution phase may be W, C, and Ti.

The binding phase may include an iron group metal. Examples of the iron group metal may include Co (cobalt) and Ni (nickel). The binding phase may include at least one of Co and Ni. The binding phase may include the iron group metal as a main component. The binding phase is servable as a phase that bonds the hard phases adjacent to each other. The iron group metals including Co and Ni as examples may have the largest value of percent by mass among components included in the binding phase.

Individual compositions of the hard phase, the solid solution phase, and the binding base may be measured with, for example, Energy-dispersive X-ray Spectroscopy (EDS). Measurements may be made using the EDS included in an electron microscope. Examples of the electron microscope may include Scanning Electron Microscope (SEM) and Transmission Electron Microscope (TEM).

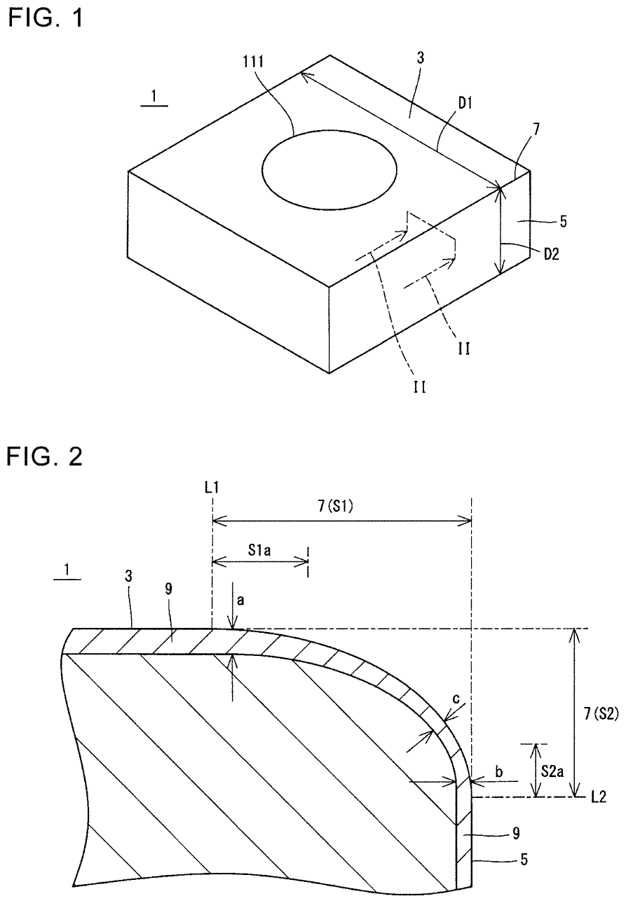

The cemented carbide 1 may include a rake surface 3 and a flank surface 5 as in a non-limiting embodiment illustrated in FIGS. 1 and 2. That is, the cemented carbide 1 may have a cutting tool shape. The cemented carbide 1 may have a plate shape. For example, the cemented carbide 1 may have a quadrangular plate shape as in the non-limiting embodiment illustrated in FIG. 1. In this case, an upper surface may be the rake surface 3, and a lateral surface may be the flank surface 5. The shape of the cemented carbide 1 is not limited to the quadrangular plate shape. For example, the rake surface 3 may have a triangular shape, a pentagonal shape, a hexagonal shape, or a circular shape.

The cemented carbide 1 is not limited to having specific dimensions. For example, a width D1 of the rake surface 3 may be set to 3-20 mm. A width D2 of the flank surface 5 may be set to 5-20 mm. The width D1 and the width D2 may be dimensions in a direction orthogonal to an intersecting ridgeline part of the rake surface 3 and the flank surface 5.

The cemented carbide 1 may include an intersecting region 7 of the rake surface 3 and the flank surface 5. The intersecting region 7 is namely a cutting edge ridgeline part, and a cutting edge may be subjected to honing treatment as cutting edge treatment. A part of the cutting edge subjected to the cutting edge treatment may be the cutting edge ridgeline part. The honing treatment may be a treatment method where the cutting edge is polished up by pressing a hone against the cutting edge while rotating and reciprocating the hone. In other words, the intersecting region 7 may be a region subjected to the honing treatment in the intersecting ridgeline part of the rake surface 3 and the flank surface 5. Specifically, a region of a range S1 from a boundary part L1 on a side of the rake surface 3 to the flank surface 5 of the cutting edge ridgeline part in top view (plan view) from the rake surface 3, and a range S2 from a boundary part L2 on a side of the flank surface 5 to the rake surface 3 of the cutting edge ridgeline part in top view (plan view) from the flank surface 5 may be the intersecting region 7 (refer to FIG. 2).

If it is difficult to determine the boundary part L1, a position 80 μm away from the flank surface 5 in top view from the rake surface 3 may be regarded as the boundary part L1. If it is difficult to determine the boundary part L2, a position 60 μm away from the rake surface 3 in top view from the flank surface 5 may be regarded as the boundary part L2.

The intersecting region 7 may have a convex curved surface shape. The shape of the intersecting region 7 is not limited to the convex curved surface shape. The intersecting region 7 may have, for example, a planar shape subjected to chamfer treatment. The intersecting region 7 having the planar shape is inclined relative to the rake surface 3 and the flank surface 5. It is therefore easy to determine an end part on a side of the rake surface 3 in the intersecting region 7, and an end part on a side of the flank surface 5 in the intersecting region 7. If the intersecting region 7 has the convex curved surface shape, it is easy to determine the end part on the side of the rake surface 3 in the intersecting region 7, and the end part on the side of the flank surface 5 in the intersecting region 7 from a difference between the rake surface 3 and the flank surface 5 each having the planar shape, and the intersecting region 7 having the convex curved surface shape.

The intersecting region 7 may be located on a part or the whole of the intersecting ridgeline part of the rake surface 3 and the flank surface 5. The intersecting region 7 is usable for machining a workpiece.

The cemented carbide 1 may include a β-free layer 9 composed only of WC and an iron group metal on a surface of the intersecting region 7 as in the non-limiting embodiment illustrated in FIG. 2. The β-free layer 9 is a layer that is rich in iron group metal, such as Co, and has excellent toughness, and is servable as a layer that absorbs an impact caused between itself and a workpiece so as to avoid a fracture. Therefore, if the cemented carbide 1 includes the β-free layer 9 on the surface of the intersecting region 7, the intersecting region 7 is less likely to fracture.

As used herein, “the β-free layer 9 composed only of WC and the iron group metal” means that almost all of components constituting the β-free layer 9 are WC and the iron group metal. The β-free layer 9 may include impurities unavoidable during a manufacturing process. A total content of the impurities may be 3% by mass or less, in other words, a total value of the WC and the iron group metal may be 97% by mass or more.

The cemented carbide 1 may include the β-free layer 9 on the entire surface of the intersecting region 7. In other words, the entire surface of the intersecting region 7 may be the β-free layer 9 in the cemented carbide 1. The cemented carbide 1 may also include the β-free layer 9 on a surface other than the intersecting region 7. The iron group metal in the β-free layer 9 may have the same composition as the iron group metal in the binding phase. The β-free layer 9 may be identified by, for example, the EDS.

Here, an average thickness of the β-free layer 9 on the rake surface 3 in the intersecting region 7 may be referred to as “a,” and an average thickness of the β-free layer 9 on the flank surface 5 in the intersecting region 7 may be referred to as “b.” A relationship between “a” and “b” may satisfy b<a. In this case, the intersecting region 7 is less prone to cracking, chipping, etc., and the intersecting region 7 is much less likely to fracture. Consequently, the cemented carbide 1 has enhanced fracture resistance.

The relationship between “a” and “b” may satisfy 1<a/b≤2.5. In this case, it is easy to improve the fracture resistance of the cemented carbide 1.

The relationship between “a” and “b” may satisfy 1.5≤a/b≤2.5. In this case, it is easier to improve the fracture resistance of the cemented carbide 1.

The average thickness of the β-free layer 9 of the rake surface 3 in the intersecting region 7 may indicate the average thickness of the β-free layer 9 at an end part on a side of the rake surface 3 in the intersecting region 7 as viewed from the rake surface 3. Therefore, the average thickness of the β-free layer 9 of the rake surface 3 in the intersecting region 7 may be rephrased as an average thickness of the β-free layer 9 in a region S1a located at the end part on the side of the rake surface 3 in the intersecting region 7. The region Sla may be, for example, a region extending 10 μm from the boundary part L1.

The average thickness of the β-free layer 9 of the flank surface 5 in the intersecting region 7 may indicate the average thickness of the β-free layer 9 at an end part on a side of the flank surface 5 in the intersecting region 7 as viewed from the flank surface 5. Therefore, the average thickness of the β-free layer 9 of the flank surface 5 in the intersecting region 7 may be rephrased as an average thickness of the β-free layer 9 in a region S2a located at the end part on the side of the flank surface 5 in the intersecting region 7. The region S2a may be, for example, a region extending 5 μm from the boundary part L2.

The thickness of the β-free layer 9 may be measured by a cross-sectional observation using an electron microscope. A cross section to be observed may be, for example, a cross section as illustrated in FIG. 2. That is, the cross section to be observed may be a cross section orthogonal to the intersecting region 7 in top view (plan view) from the rake surface 3. The thickness of the β-free layer 9 may be measured at 5 or more measuring points at 1 μm intervals with a width of 5 μm or more at an arbitrary position of the region S1a or the region S2a in the cross section, and an average value thereof may be calculated.

Here, “a” and “b” are not limited to a specific thickness. For example, “a” may be set to 7.3-14.3 μm, and “b” may be set to 2.9-13 μm.

An average thickness of the β-free layer 9 in the intersecting region 7 may monotonically decrease as going from a side of the rake surface 3 to a side of the flank surface 5. If the average thickness of the β-free layer 9 has the above configuration, the intersecting region 7 is much less prone to cracking and chipping, and the intersecting region 7 is much less likely to fracture.

The intersecting region 7 may further include a region which is located between an end part on a side of the rake surface 3 and an end part on a side of the flank surface 5 and in which an average thickness of the β-free layer 9 is “c.” In other words, the intersecting region 7 may further include another region between the region S1a and the region S2a, and the average thickness of the β-free layer 9 in the region may be “c.” In this case, “c” may be smaller than each of “a” and “b.” If the average thickness of the β-free layer 9 has the above configuration, the β-free layer 9 on a cutting edge can be made thin, thereby maintaining cutting performance of the cutting edge.

In cases where the intersecting region 7 in section view has the convex curved surface shape as in the non-limiting embodiment illustrated in FIG. 2, the region where the average thickness of the β-free layer 9 is “c” may be located at a part having a minimum radius of curvature in the intersecting region 7. Specifically, the radius of curvature of the intersecting region 7 in the region where the average thickness of the β-free layer 9 is “c” may be smaller than a radius of curvature of the intersecting region 7 in each of the region Sla and the region S2a. If the intersecting region 7 has the above configuration, the cutting edge can be made sharp, thereby maintaining the cutting performance of the cutting edge.

The region where the average thickness of the β-free layer 9 is “c” may be located on a side of the flank surface 5 than a side of the rake surface 3. In other words, the region where the average thickness of the β-free layer 9 is “c” may be located closer to the flank surface 5 than the rake surface 3. In this case, the thickness of the β-free layer 9 of the rake surface 3 can be increased to produce a benefit of improving fracture resistance.

A width of the intersecting region 7 in plan view from the rake surface 3 may be larger than a width of the intersecting region 7 in plan view from the flank surface 5. In this case, an increase in radius of curvature of honing of the rake surface 3 produces a benefit of improving chipping resistance performance.

### <Method for Manufacturing Cemented Carbide>

A method for manufacturing a cemented carbide in a non-limiting embodiment of the present disclosure is described below by exemplifying the case of manufacturing a cemented carbide 1.

Firstly, WC powder, Co powder, and TiC powder may be prepared as raw material powder. A proportion of the Co powder may be 4-12% by mass. A proportion of the Tic powder may be 0.5-15% by mass. The rest may be the WC powder.

Mean particle diameters of the raw material powders may be suitably selected in a range of 0.1-10 μm. The mean particle diameters of the raw material powders may be values measured by micro track method.

A molded body may be obtained by mixing the prepared raw material powders, followed by molding so as to include a rake surface 3 and a flank surface 5. This may include previously molding into a shape obtained by chamfering an intersecting ridgeline part of the rake surface 3 and the flank surface 5 by metal mold press. In this case, it is easy to form a β-free layer 9 on a surface of an intersecting region 7. The chamfering may include forming the intersecting ridgeline part into a convex curved surface shape and a planar shape.

A cemented carbide 1 may be obtained by subjecting the obtained molded body to debinding treatment, followed by sintering. The sintering may be carried out in a non-oxidizing atmosphere, such as vacuum, argon atmosphere, and nitrogen atmosphere. A sintering temperature may be 1450-1600° C. Sintering time may be 0.5-3 hours. It is easy to form the β-free layer 9 on a surface of the cemented carbide 1 if the sintering is carried out at the above sintering temperature and for the above sintering time.

The obtained cemented carbide 1 may be subjected to honing treatment to form the intersecting region 7 of the rake surface 3 and the flank surface 5. Subsequently, a thickness of the β-free layer 9 may be adjusted by polishing the intersecting region 7 so that a relationship between “a” and “b” can satisfy b<a. The polishing may be carried out by, for example, brush treatment, blast treatment, and barrel treatment.

The above manufacturing method is one embodiment of the method for manufacturing the cemented carbide 1. Therefore, it is needless to say that the cemented carbide 1 is not limited to one which is manufactured by the above manufacturing method.

### <Coated Tool>

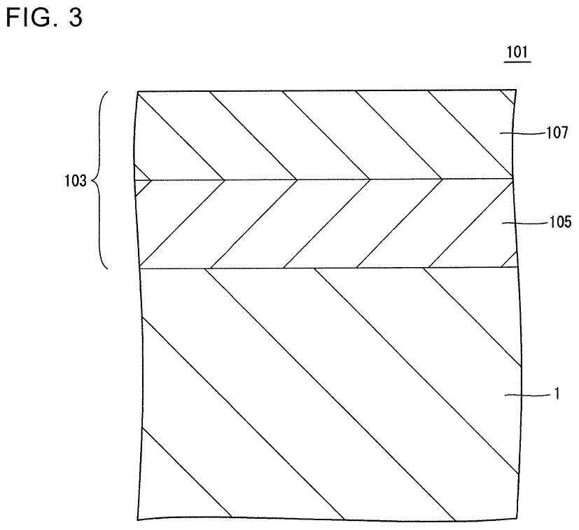

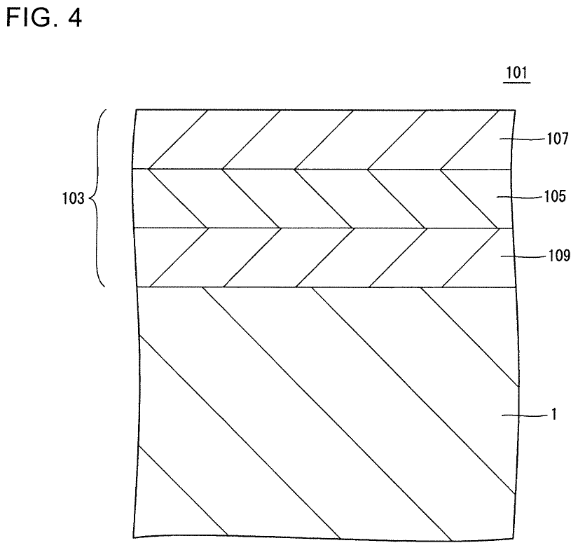

A coated tool 101 in a non-limiting embodiment of the present disclosure is described below with reference to FIGS. 3 and 4 by exemplifying the case of including the cemented carbide 1 described above.

The coated tool 101 may include the cemented carbide 1 and a coating layer 103 located on a surface of the cemented carbide 1 as in the non-limiting embodiment illustrated in FIGS. 3 and 4. The coated tool 101 may include the cemented carbide 1 as a base. If the coated tool 101 includes the cemented carbide 1, it is easy to improve cutting performance, such as intermittent performance, because of high fracture resistance of the cemented carbide 1. This leads to high durability of the coated tool 101.

The coating layer 103 may be located on the whole or a part of the surface of the cemented carbide 1. That is, the coating layer 103 may be located on at least the part of the surface of the cemented carbide 1.

The coating layer 103 may be deposited by Chemical Vapor Deposition (CVD) method. In other words, the coating layer 103 may be a CVD film. Alternatively, the coating layer 103 may be a PVD film deposited by Physical Vapor Deposition (PVD) method.

The coating layer 103 may be configured with a single layer, or may be configured with a plurality of laminated layers. Examples of composition of the coating layer 103 may include TiCN (titanium carbonitride), Al₂O₃ (alumina), and TiN (titanium nitride).

The coating layer 103 may include a TiCN layer 105 and an Al₂O₃ layer 107 in sequence from a side of the cemented carbide 1 as in the non-limiting embodiment illustrated in FIG. 3. The TiCN layer 105 may be in contact with the cemented carbide 1. The Al₂O₃ layer 107 may be in contact with the TiCN layer 105.

The coating layer 103 may include a TiN layer 109, the TiCN layer 105, and the Al₂O₃ layer 107 in sequence from a side of the cemented carbide 1 as in the non-limiting embodiment illustrated in FIG. 4. The TiN layer 109 may be in contact with the cemented carbide 1. The TiCN layer 105 may be in contact with the TiN layer 109. The Al₂O₃ layer 107 may be in contact with the TiCN layer 105.

The coating layer 103 is not limited to having a specific thickness. For example, a thickness of the TiCN layer 105 may be set to approximately 1.0-15 μm. A thickness of the Al₂O₃ layer 107 may be set to approximately 1-15 μm. A thickness of the TiN layer 109 may be set to approximately 0.1-5 μm. The thickness of the coating layer 103 may be measured by a cross sectional observation using an electron microscope. The thickness of the coating layer 103 may be an average value. For example, the thickness may be measured at 10 or more measuring points at 1 μm intervals with a width of 10 μm or more at an arbitrary position of the individual layers, and an average value thereof may be calculated.

The coated tool 101 may include a through hole 111. For the convenience of description, FIG. 1 illustrates the through hole 111. The through hole 111 is usable for attaching a fixing screw or clamping member when holding the coated tool 101 in a holder. The through hole 111 may be formed from an upper surface (rake surface 3) to a lower surface located on a side opposite to the upper surface, and the through hole 111 may also open into these surfaces. There is no problem even if the through hole 111 is configured to open into regions opposed to each other in a lateral surface (flank surface 5).

### <Method for Manufacturing Coated Tool>

A method for manufacturing a coated tool in a non-limiting embodiment of the present disclosure is described below by exemplifying the case of manufacturing a coated tool 101.

The coated tool 101 may be obtained by depositing a coating layer 103 on a surface of a cemented carbide 1 by CVD method.

A TiCN layer 105 may be deposited as follows. Firstly, a mixed gas composed of 0.1-10% by volume of titanium tetrachloride (TiCl₄) gas, 10-60% by volume of nitrogen (N₂) gas, 0.1-15% by volume of methane (CH₄) gas, and the rest that is hydrogen (H₂) gas may be prepared as a reaction gas composition. The mixed gas may be introduced into a chamber to deposit the TiCN layer 105 by setting a temperature of 800-1100° C. and a pressure of 5-30 kPa.

An Al₂O₃ layer 107 may be deposited as follows. Firstly, a mixed gas composed of 0.5-5% by volume of aluminum trichloride (AlCl₃) gas, 0.5-3.5% by volume of hydrogen chloride (HCL) gas, 0.5-5% by volume of carbon dioxide (CO₂) gas, 0.5% by volume or less of hydrogen sulfide (H₂S) gas, and the rest that is hydrogen (H₂) gas may be prepared as a reaction gas composition. The mixed gas may be introduced into the chamber to deposit the Al₂O₃ layer 107 by setting a temperature of 930-1010° C. and a pressure of 5-10 kPa.

A TiN layer 109 may be deposited as follows. Firstly, a mixed gas composed of 0.1-10% by volume of titanium tetrachloride (TiCl₄) gas, 10-60% by volume of nitrogen (N₂) gas, and the rest that is hydrogen (H₂) gas may be prepared as a reaction gas composition. The mixed gas may be introduced into the chamber to deposit the TiN layer 109 by setting a temperature of 800-1010° C. and a pressure of 10-85 kPa.

The above manufacturing method is an embodiment of the method for manufacturing the coated tool 101. Therefore, it is needless to say that the coated tool 101 is not limited to one which is manufactured by the above manufacturing method.

### <Cutting Tool>

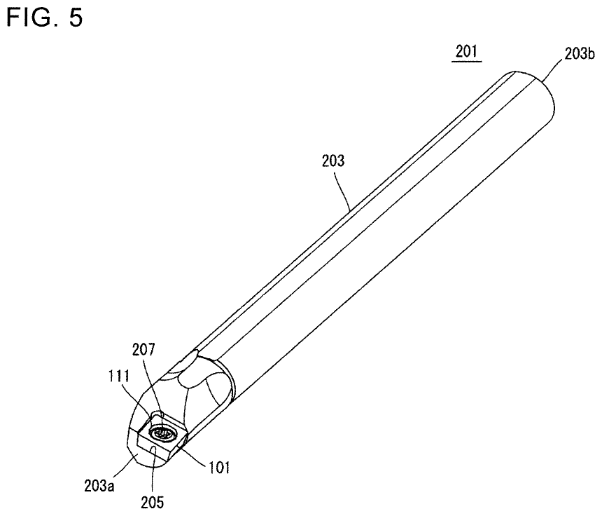

A cutting tool 201 in a non-limiting embodiment of the present disclosure is described below with reference to FIG. 5 by exemplifying the case of including the coated tool 101.

The cutting tool 201 may include a holder 203 that extends from a first end 203a toward a second end 203b and includes a pocket 205 on a side of the first end 203a, and the coated tool 101 located in the pocket 205. If the cutting tool 201 includes the coated tool 101, the cutting tool 201 has high wear resistance and becomes capable of performing a stable machining because of the high durability of the coated tool 101.

The pocket 205 may be a part to which the coated tool 101 is attached. The pocket 205 may open into an outer peripheral surface of the holder 203 and an end surface on a side of the first end 203a.

The coated tool 101 may be attached to the pocket 205 so that an intersecting region 7 can be protruded outward from the holder 203. The coated tool 101 may also be attached to the pocket 205 by a fixing screw 207. That is, the coated tool 101 may be attached to the pocket 205 by inserting the fixing screw 207 into a through hole 111 of the coated tool 101, and by inserting a front end of the fixing screw 207 into a screw hole formed in the pocket 205 so as to ensure engagement between screw parts. In this case, a lower surface of the coated tool 101 may be directly contacted with the pocket 205, or alternatively, a sheet may be held between the coated tool 101 and the pocket 205.

For example, steel and cast iron are usable as a material of the holder 203. If the material of the holder 203 is steel, the holder 203 has high toughness.

The cutting tool 201 used for a so-called turning process is exemplified in the embodiment illustrated in FIG. 5. Examples of the turning process may include internal machining, external machining, and grooving process. The use of the cutting tool 201 is not limited to the turning process. For example, there is no problem even if the cutting tool 201 is used for a milling process.

Although the present disclosure is described in detail below by giving Examples, the present disclosure is not limited to the following Examples.

### Examples

### [Samples Nos. 1 to 6]

### <Manufacturing of Cemented Carbide>

Firstly, WC powder whose mean particle diameter was 9 μm, Co powder whose mean particle diameter was 1.5 μm, and TiC powder whose mean particle diameter was 1.5 μm were prepared as raw material powder. These mean particle diameters of the raw material powders were values measured by micro-track method.

Subsequently, a molded body was obtained by mixing 7% by mass of the Co powder, 2% by mass of the Tic powder, and the rest that was the WC powder at their respective proportions, followed by press molding into a cutting tool shape (CNMG120408) so as to include a rake surface and a flank surface. Samples Nos. 1 to 5 were molded into such a shape that an intersecting ridgeline part of the rake surface and the flank surface was chamfered into a convex curved surface shape by metal mold press.

Each of obtained molded bodies was subjected to debinding treatment and was sintered while being kept at 1500° C. for one hour, thereby obtaining a cemented carbide. The obtained cemented carbide was subjected to honing treatment to form an intersecting region of the rake surface and the flank surface.

A composition of the obtained cemented carbide was measured with an EDS. Specifically, a cross-sectional observation was made using the EDS included in an SEM, and measurements were made under conditions that five locations were measured at 5000-20000× magnification to obtain an average value thereof.

Results of the measurements with the EDS showed that all of obtained cemented carbides included a hard phase containing W and C as a main component, a solid solution phase containing W, C, and Ti as a main component, and a binding phase containing an iron group metal (Co) as a main component. The cemented carbides of Samples Nos. 1 to 5 included a β-free layer composed only of WC and an iron group metal (Co) on an entire surface of the intersecting region.

In each of Samples Nos. 1 to 5, the intersecting region was subjected to polishing (brush or blast treatment) so that “a” and “b” can have values presented in Table 1. Values of “a” and “b” presented in a column of “average thickness of β-free layer in intersecting region” in Table 1 are values measured according to the method exemplified above.

### <Evaluation>

A machining evaluation was made on the obtained cemented carbides. Specifically, a coated tool was manufactured by depositing a TiN layer having a thickness of 1 μm, a TiCN layer having a thickness of 10 μm, and an Al₂O₃ layer having a thickness of 6 μm in sequence from a side of the cemented carbide (base) by CVD method. Thereafter, the machining evaluation was made under the following conditions. A thickness of each of these layers is an average value.
Machining Type: Turning
Cutting Speed: 150 m/min
Feed: 0.4 mm/rev
Depth of Cut: 0.5 mm
Workpiece: SCM440 ϕ200 round rod
Machining State: WET

Evaluation results are shown in Table 1. The term “number of impacts until occurrence of fracture of cutting edge” indicates the number of impacts until the cutting edge fractures during a machining process. This is also called an intermittent performance evaluation.

TABLE 1

| | Average thickness of | | | Evaluation results |
|---|---|---|---|---|
| | β -free layer | | | Number of impacts |
| | in intersecting region | | | until occurrence of fracture |
| Sample | (μm) | | | of cutting edge |
| No. | a | b | a/b | (times) |
| 1 | 7.3 | 2.9 | 2.5 | 30000 or more |
| 2 | 8.6 | 6.6 | 1.3 | 25000 |
| 3 | 11.4 | 5.7 | 2 | 30000 or more |
| 4 | 14.3 | 13 | 1.1 | 9000 |
| 5 | 11.4 | 11.4 | 1 | 900 |
| 6 | 0 | 0 | 0 | 650 |

Samples Nos. 1 to 4 apparently showed improved stability compared to Samples Nos. 5 and 6. Particularly, Sample No. 6 included no β-free layer on the surface of the intersecting region, had the smallest number of impacts, had low wear resistance at the cutting edge, and it was difficult to perform a stable machining as a cutting tool.

### DESCRIPTION OF THE REFERENCE NUMERAL

1 cemented carbide
3 rake surface
5 flank surface
7 intersecting region
9 β-free layer
101 coated tool
103 coating layer
105 TiCN layer
107 Al₂O₃ layer
109 TiN layer
111 through hole
201 cutting tool
203 holder
203a first end
203b second end
205 pocket
207 fixing screw

1. A cemented carbide, comprising:
a hard phase comprising W and C;
a solid solution phase comprising W, C, and Ti; and
a binding phase comprising an iron group metal, wherein
the cemented carbide comprises a β-free layer composed only of WC and an iron group metal on a surface of an intersecting region of a rake surface and a flank surface in the cemented carbide,
an average thickness of the β-free layer of the rake surface in the intersecting region is “a,”
an average thickness of the β-free layer of the flank surface in the intersecting region is “b,” and
a relationship between “a” and “b” satisfies b<a.

2. The cemented carbide according to claim 1, wherein the relationship between “a” and “b” satisfies 1<a/b≤2.5.

3. The cemented carbide according to claim 1, wherein an average thickness of the β-free layer in the intersecting region monotonically decreases as going from a side of the rake surface to a side of the flank surface.

4. The cemented carbide according to claim 1, wherein
the intersecting region comprises a region which is located between an end part on a side of the rake surface and an end part on a side of the flank surface and in which an average thickness of the β-free layer is “c,” and
the “c” is smaller than each of the “a” and the “b.”

5. The cemented carbide according to claim 4, wherein the region where the average thickness of the β-free layer is “c” is located at a part having a minimum radius of curvature in the intersecting region.

6. The cemented carbide according to claim 4, wherein the region where the average thickness of the β-free layer is “c” is located closer to a side of the flank surface than a side of the rake surface.

7. The cemented carbide according to claim 1, wherein a width of the intersecting region in plan view from the rake surface is larger than a width of the intersecting region in plan view from the flank surface.

8. A coated tool, comprising:
the cemented carbide according to claim 1; and
a coating layer located on a surface of the cemented carbide.

9. The coated tool according to claim 8, wherein the coating layer comprises a TiCN layer and an Al₂O₃ layer in sequence from a side of the cemented carbide.

10. The coated tool according to claim 8, wherein the coating layer comprises a TiN layer, a TiCN layer, and an Al₂O₃ layer in sequence from a side of the cemented carbide.

11. A cutting tool, comprising:
a holder that extends from a first end toward a second end and comprises a pocket on a side of the first end; and
the coated tool according to claim 8, which is located in the pocket.
